(19) United States
(12) Patent Application Publication
(10) Pub. No.: US 2017/0194451 A1
(43) Pub. Date: Jul. 6, 2017

(54) Schottky Barrier Semiconductor Device Having a Nanoscale Film Interface

(71) Applicant: WIN Semiconductors Corp., Tao Yuan City (TW)

(72) Inventors: Chang-Hwang HUA, Tao Yuan City (TW); Winson SHAO, Tao Yuan City (TW)

(21) Appl. No.: 15/138,500

(22) Filed: Apr. 26, 2016

(30) Foreign Application Priority Data
Jan. 6, 2016 (TW) 105100308

(51) Int. Cl. H01L 29/47; H01L 29/205; H01L 29/812; H01L 29/20; H01L 29/872; H01L 29/778

(52) U.S. Cl. CPC H01L 29/475; H01L 29/872; H01L 29/778; H01L 29/812; H01L 29/2003; H01L 29/205; H01L 29/1608

(57) ABSTRACT

A Schottky barrier semiconductor device having a nanoscale film interface comprises a Schottky barrier layer and a metal electrode; wherein a nanoscale film interface layer is formed on a top surface of the Schottky barrier layer, a thickness of the nanoscale film interface layer is greater than 3 Å and smaller than 20 Å, the nanoscale film interface layer is made of at least one oxide; the metal electrode is formed on the nanoscale film interface layer and contacted with the nanoscale film interface layer.

### FIELD OF THE INVENTION

The present invention relates to a Schottky barrier semiconductor device having a nanoscale film interface, which may reduce the interface trap to improve the characteristics of the Schottky barrier semiconductor device.

### BACKGROUND OF THE INVENTION

Due to the great potential to the application of high power and high frequency, high electron mobility transistor (HEMT) has attracting much attention. However, high electron mobility transistor has been some problems, such as leakage current, gate metal diffusion, gate-lag phenomenon and drain-lag phenomenon, which limit its application. Generally, the metal-semiconductor field effect transistor having the Schottky interface also has the mentioned above problems. Please refer to FIG. 4, which is the sectional schematic view of the metal-semiconductor field effect transistor of the conventional technology. The structure of the metal-semiconductor field effect transistor 4 comprises a substrate 40, a Schottky barrier layer 41, a gate electrode 42, a drain electrode 43, a source electrode 44 and a dielectric layer 45. The Schottky barrier layer 41 is formed on the substrate 40. The gate electrode 42 is formed on the Schottky barrier layer 41 and the gate electrode 42 is contacted with the Schottky barrier layer 41 (that is the Schottky contact) to form a Schottky junction. Usually before forming the gate electrode 42, the dielectric layer 45 is formed on the Schottky barrier layer 41 and the dielectric layer 45 is etched to form a dielectric layer recess. And then the gate electrode 42 is formed on the dielectric layer 45 and covers the dielectric layer recess such that the gate electrode 42 is contacted with the Schottky barrier layer 41 at the bottom of the dielectric layer recess to form the Schottky junction. The drain electrode 43 and the source electrode 44 are formed at respectively the left and the right sides of the gate electrode 42 on the Schottky barrier layer 41. And the drain electrode 43 and the source electrode 44 form the ohmic contact with the Schottky barrier layer 41 respectively. When applying a pulsed voltage on the gate electrode 42 of the metal-semiconductor field effect transistor 4, a drain current is immediately but only partially turned on (the partially turned on drain current is I_{g0}). Then the drain current will gradually and slowly change over time, until it reaches steady state (steady state drain current I_{gs}). This phenomenon is called gate-lag phenomenon (gate-lag effect). The rate of gate-lag effect (or say gate-lag) is defined as (I_{gs}−I_{g0})/I_{gs}*100%. The higher the rate of gate-lag effect is, the more serious the gate-lag effect is. Gate-lag effect will affect certain digital circuits as well as the efficiency of high precision analog circuits. For example, when a pulse passes through a series of inverters, serious gate-lag effect will cause the width of the pulse becoming narrower. Even further the width of the pulse will become 0, which will cause the series of inverters not functioning properly. The major factor generating the gate-lag effect is the interface trap (or say surface trap) of the Schottky barrier layer 41, which includes the interface trap of the Schottky junction formed by the contact of the gate electrode 42 and the Schottky barrier layer 41 and the interface trap of the Schottky barrier layer 41 between the gate electrode 42 and the drain electrode 43, while the interface trap of the Schottky barrier layer 41 between the source electrode 44 and the gate electrode 42 may also affect the gate-lag effect. When a drain current is turned on, the interface trap of the Schottky barrier layer 41 captures and confines the passing through carriers. These carriers will take time to be released gradually from the confine of the interface trap of the Schottky barrier layer 41. Thereby generating gate-lag effect.

Similarly, when applying a pulsed voltage on the drain electrode 43 of the metal-semiconductor field effect transistor 4, a drain current is immediately but only partially turned on (the partially turned on drain current is I_{d0}). Then the drain current will gradually and slowly change over time, until it reaches steady state (steady state drain current I_{ds}). This phenomenon is called drain-lag phenomenon (drain-lag effect). The rate of drain-lag effect (or say drain-lag) is defined as (I_{ds}−I_{d0})/I_{ds}*100%. The major factor generating the drain-lag effect comes from the substrate 40 which includes the defect of the substrate and the epitaxial structure, the impurity and non-uniformly doping and the defect of the Schottky barrier layer 41 which includes the defect of the sub-structure such as a Schottky barrier sub-layer (not shown in Figure), a channel sub-layer (not shown in Figure) and a buffer sub-layer (not shown in Figure). And the interface trap of the Schottky barrier layer 41 may also affect the drain-lag effect.

The leakage current phenomenon of the metal-semiconductor field effect transistor 4 mainly includes the gate leakage current. The drain current may easily leak out through the Schottky junction between the gate electrode 42 and the Schottky barrier layer 41, which is called the gate leakage current. The leakage current phenomenon of the metal-semiconductor field effect transistor 4 also includes drain leakage current.

The conducting metal of the gate electrode 42 of the metal-semiconductor field effect transistor 4 is usually made of gold or copper. However gold or copper may easily diffuse from the gate electrode 42 through the Schottky junction into the Schottky barrier layer 41. This is called gate metal diffusion phenomenon. Gate metal diffusion phenomenon may damage the structural integrity of the Schottky junction between the gate electrode 42 and the Schottky barrier layer 41, such that the leakage of the metal-semiconductor field effect transistor 4 is increased. Not only the electrical characteristics but also the efficiency and the reliability are affected.

The Schottky diode of the conventional technology also has leakage current and metal diffusion problems. Besides, the Schottky diode of the conventional technology also has a current collapse phenomenon similar to the gate-lag effect of the metal-semiconductor field effect transistor, which may limit its application. Please refer to FIG. 5, which is the sectional schematic view of the Schottky diode of the conventional technology. The structure comprises a Schottky barrier layer 50, a first electrode 51 and a second electrode 52. The Schottky barrier layer 50 and the first electrode 51 form a Schottky junction, while the Schottky barrier layer 50 and the second electrode 52 form an ohmic contact. The current collapse phenomenon of the Schottky diode is that when applying a pulsed voltage on the first electrode 51 of the Schottky diode 5, the current is immediately but only partially turned on. Then the current will gradually and slowly change over time, until it reaches steady state. During the time the voltage is fixed, hence the phenomenon seems like that the resistance is dynamically changing such that the current is dynamically changing. Thus, this phenomenon is also called dynamic on-resistance (Dynamic Rₒₙ).

Accordingly, the present invention has developed a new design which may avoid the above mentioned drawbacks, may reduce the interface trap of the Schottky barrier layer, may significantly enhance the performance of the devices and may take into account economic considerations. Therefore, the present invention then has been invented.

### SUMMARY OF THE INVENTION

There are some technical problems that the present invention is seeking to solve, wherein the main technical problems are to improve the gate-lag effect of the metal-semiconductor field effect transistor and to improve the current collapse phenomenon (or say dynamic on-resistance phenomenon). Other technical problems that the present invention is seeking to solve includes: improving the drain-lag effect of the metal-semiconductor field effect transistor, reducing the leakage current of the metal-semiconductor field effect transistor, reducing the leakage current of the Schottky diode, reducing the gate metal diffusion of the metal-semiconductor field effect transistor and reducing the metal diffusion of the Schottky diode.

In order to solve the problems mentioned the above and to achieve the expected effect, the present invention provides a Schottky barrier semiconductor device having a nanoscale film interface, which comprises a Schottky barrier layer and a metal electrode. A nanoscale film interface layer is formed on a top surface of the Schottky barrier layer, wherein a thickness of the nanoscale film interface layer is greater than 3 Å and less than 20 Å, the nanoscale film interface layer is made of at least one oxide. The metal electrode formed on the nanoscale film interface layer and contacted with the nanoscale film interface layer. By depositing the nanoscale film interface layer to reduce the interface trap of the top surface of the Schottky barrier layer. To the application of the metal-semiconductor field effect transistor, the gate-lag effect and the drain-lag effect of the metal-semiconductor field effect transistor will be improved. And due to the nanoscale film interface layer is made of oxide, hence the gate metal diffusion may be reduced and the gate leakage current may also be reduced too. To the application of the Schottky diode, the current collapse phenomenon may be improved. And due to the nanoscale film interface layer is made of oxide, hence the leakage current and the metal diffusion of the Schottky diode may also be reduced.

In an embodiment of the Schottky barrier semiconductor device having a nanoscale film interface, wherein the nanoscale film interface layer is made of at least one material selected from the group consisting of an aluminum oxide, a silicon oxide, a gallium oxide, a germanium oxide, a nickel oxide, a tantalum oxide and a palladium oxide.

In an embodiment of the Schottky barrier semiconductor device having a nanoscale film interface, wherein the Schottky barrier semiconductor device is a Schottky diode.

In an embodiment of the Schottky barrier semiconductor device having a nanoscale film interface, further comprises a second metal electrode, wherein the second metal electrode is formed on a bottom surface of the Schottky barrier layer, and the second metal electrode and the Schottky barrier layer form an ohmic contact.

In an embodiment of the Schottky barrier semiconductor device having a nanoscale film interface, further comprises a substrate and a second metal electrode, wherein the Schottky barrier layer is formed above the substrate, the second metal electrode is formed below the substrate.

In an embodiment of the Schottky barrier semiconductor device having a nanoscale film interface, further comprises a substrate, wherein the Schottky barrier layer is formed on the substrate.

In an embodiment of the Schottky barrier semiconductor device having a nanoscale film interface, wherein the substrate is made of one material selected from the group consisting of GaAs, sapphire, InP, SiC and GaN.

In an embodiment of the Schottky barrier semiconductor device having a nanoscale film interface, wherein the Schottky barrier semiconductor device is a high electron mobility transistor or a metal-semiconductor field transistor.

In an embodiment of the Schottky barrier semiconductor device having a nanoscale film interface, wherein the metal electrode is a gate electrode.

In an embodiment of the Schottky barrier semiconductor device having a nanoscale film interface, wherein the gate electrode includes a conduct layer and a contact layer, wherein the contact layer is contacted with the nanoscale film interface layer.

In an embodiment of the Schottky barrier semiconductor device having a nanoscale film interface, wherein the gate electrode further comprises a diffusion barrier layer, wherein the diffusion barrier layer is formed in between the contact layer and the conduct layer.

In an embodiment of the Schottky barrier semiconductor device having a nanoscale film interface, further comprises a source electrode and a drain electrode, wherein the source electrode and the drain electrode are formed at respectively the left and the right sides of the metal electrode on the Schottky barrier layer.

In an embodiment of the Schottky barrier semiconductor device having a nanoscale film interface, further comprises a cap layer, wherein the cap layer is formed between the source electrode and the Schottky barrier layer and between the drain electrode and the Schottky barrier layer.

In an embodiment of the Schottky barrier semiconductor device having a nanoscale film interface, wherein the Schottky barrier layer comprises a barrier sub-layer and a channel sub-layer, wherein the barrier sub-layer is formed on the channel sub-layer.

In an embodiment of the Schottky barrier semiconductor device having a nanoscale film interface, wherein the Schottky barrier layer further comprises a buffer sub-layer, wherein the channel sub-layer is formed on the buffer sub-layer.

In an embodiment of the Schottky barrier semiconductor device having a nanoscale film interface, wherein the Schottky barrier layer comprises a barrier sub-layer and a buffer sub-layer, wherein the barrier sub-layer is formed on the buffer sub-layer.

In an embodiment of the Schottky barrier semiconductor device having a nanoscale film interface, wherein the Schottky barrier layer is made of at least one material selected from the group consisting of GaN, GaAs, InP, AlGaN, AlGaAs, InGaAs, InGaP, AlInP and SiC.

In an embodiment of the Schottky barrier semiconductor device having a nanoscale film interface, wherein the Schottky barrier layer is made of at least one material selected from the group consisting of group IV compound semiconductor materials, group II-VI compound semiconductor materials and group III-V compound semiconductor materials.

The present invention further provides a Schottky barrier semiconductor device having a nanoscale film oxide interface, which comprises: a Schottky barrier layer, wherein a top surface of the Schottky barrier layer is oxidized to form a nanoscale film oxide interface layer, wherein a thickness of the nanoscale film oxide interface layer is greater than 3 Å and less than 20 Å; and a metal electrode formed on the top surface of the Schottky barrier layer and contacted with the nanoscale film oxide interface layer.

In an embodiment of the Schottky barrier semiconductor device having a nanoscale film oxide interface, wherein the nanoscale film oxide interface layer is made of at least one material selected from the group consisting of an aluminum oxide, a silicon oxide, a gallium oxide, a germanium oxide, a nickel oxide, a tantalum oxide and a palladium oxide.

In an embodiment of the Schottky barrier semiconductor device having a nanoscale film oxide interface, wherein the Schottky barrier layer is made of at least one material selected from the group consisting of GaN, GaAs, InP, AlGaN, AlGaAs, InGaAs, InGaP, AlInP and SiC.

For further understanding the characteristics and effects of the present invention, some preferred embodiments referred to drawings are in detail described as follows.

### BRIEF DESCRIPTION OF DRAWINGS

FIG. 1 is the sectional schematic view of the metal-semiconductor interface of the Schottky barrier semiconductor device having a nanoscale film interface of the present invention.

FIG. 2˜FIG. 2A are the sectional schematic views of the embodiments of the Schottky barrier semiconductor device having a nanoscale film interface of the present invention.

FIG. 3˜FIG. 3H are the sectional schematic views of the embodiments of the Schottky barrier semiconductor device having a nanoscale film interface of the present invention.

FIG. 3I˜FIG. 3R are the partial enlarged gate electrode sectional schematic views of the embodiments of the Schottky barrier semiconductor device having a nanoscale film interface of the present invention.

FIG. 3S and FIG. 3T are respectively the sectional schematic view and the partial enlarged gate electrode sectional schematic view of an embodiment of the Schottky barrier semiconductor device having a nanoscale film interface of the present invention.

FIG. 4 is the sectional schematic view of the metal-semiconductor field effect transistor of the conventional technology.

FIG. 5 is the sectional schematic view of the Schottky diode of the conventional technology.

FIG. 6 is the sectional schematic view of the metal-oxide-semiconductor structure of the conventional technology.

FIG. 7 is the sectional schematic view of the metal-oxide-semiconductor field effect transistor of the conventional technology.

FIG. 8 is the comparison diagram of gate-lag and drain-lag of an embodiment of the Schottky barrier semiconductor device having a nanoscale film interface of the present invention and the metal-semiconductor field effect transistor of the conventional technology.

FIG. 8A is the gate metal diffusion analysis diagram of an embodiment of the Schottky barrier semiconductor device having a nanoscale film interface of the present invention.

FIG. 8B˜FIG. 8E are respectively the comparison diagrams of leakage current, Von, peak transconductance and zero-bais threshold voltage of two embodiments of the Schottky barrier semiconductor device having a nanoscale film interface of the present invention and the metal-semiconductor field effect transistor of the conventional technology.

### DETAILED DESCRIPTIONS OF PREFERRED EMBODIMENTS

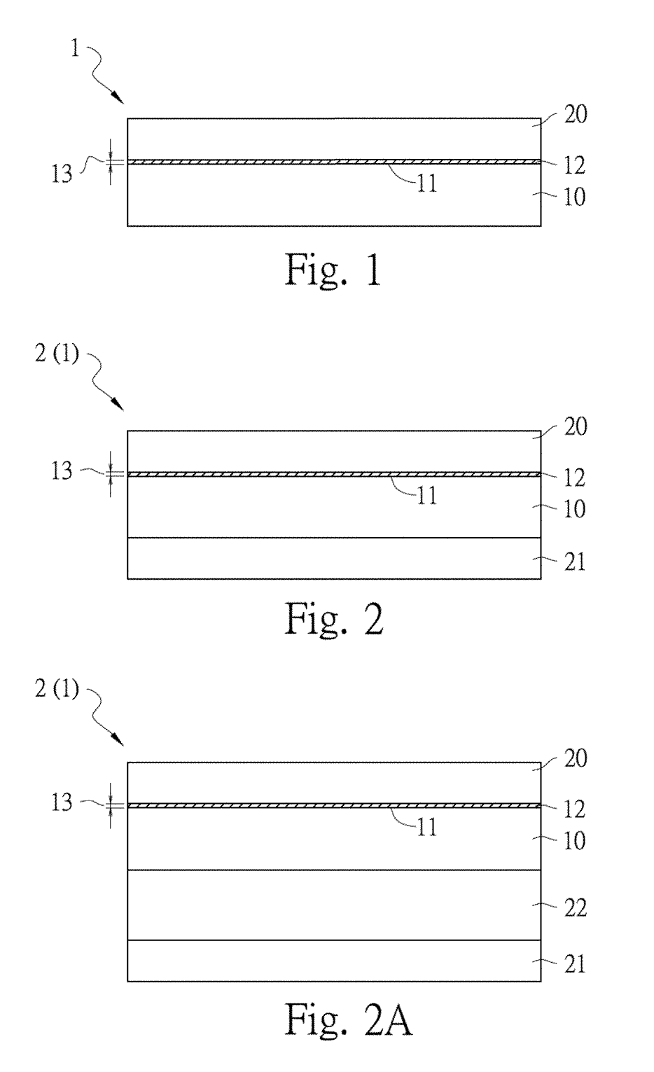

Please refer to FIG. 1, which is the sectional schematic view of the metal-semiconductor interface of the Schottky barrier semiconductor device having a nanoscale film interface of the present invention. In this embodiment, the structure of the Schottky barrier semiconductor device 1 comprises a Schottky barrier layer 10 and a metal electrode 20, wherein a nanoscale film interface layer 12 is formed on a top surface 11 of the Schottky barrier layer 10. The metal electrode 20 is formed on the nanoscale film interface layer 12 such that the metal electrode 20 is contacted with the nanoscale film interface layer 12. The nanoscale film interface layer 12 is made of an oxide or at least one oxide. The oxide is deposited on the top surface 11 of the Schottky barrier layer 10 by the Atomic Layer Chemical Vapor Deposition System (ALD) and combined with the top surface 11 of the Schottky barrier layer 10 to form the nanoscale film interface layer 12, thereby reducing the interface trap of the top surface 11 of the Schottky barrier layer 10. By depositing the nanoscale film interface layer 12 to reduce the interface trap of the top surface 11 of the Schottky barrier layer 10, thus may improve the current collapse phenomenon. And due to the nanoscale film interface layer 12 is made of oxide, hence the metal diffusion may be reduced and the leakage current may also be reduced too. However, if the thickness 13 of the nanoscale film interface layer 12 (that is the thickness of the oxide) is greater or equal to 20 Å, the thickness 13 of the nanoscale film interface layer 12 is too thick such that the resistance between the Schottky barrier layer 10 and the metal electrode 20 is too high. This will cause the characteristics of the Schottky barrier semiconductor device 1 dramatically changed, which is not the result applicant wanted. Applicant wants to improve the current collapse phenomenon, reduce leakage current and reduce the metal diffusion of the Schottky barrier semiconductor device 1 through reducing the interface trap of the top surface 11 of the Schottky barrier layer 10 by depositing the nanoscale film interface layer 12. But applicant also wants to as much as possibly preserve the rest of the characteristics the Schottky barrier semiconductor device. Therefore, although the nanoscale film interface layer 12 may reduce the interface trap of the top surface 11 of the Schottky barrier layer 10, the thickness 13 of the nanoscale film interface layer 12 may not be too thick in order to prevent the dramatically change of the characteristics of the Schottky barrier semiconductor device. Hence, the thickness 13 of the nanoscale film interface layer 12 must be within the range between greater than 3 Å and smaller than 20 Å. In a preferable embodiment, the thickness 13 of the nanoscale film interface layer 12 is within the range greater or equal to 5 Å and smaller or equal to 10 Å.

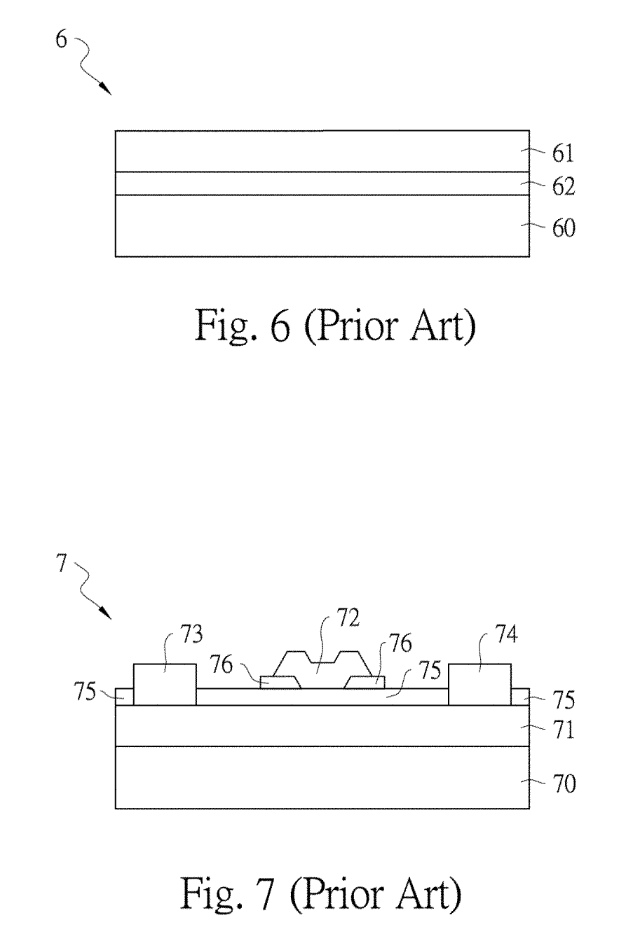

Please refer to FIG. 6, which is the sectional schematic view of the metal-oxide-semiconductor structure of the conventional technology. The metal-oxide-semiconductor structure 6 comprises a Schottky barrier layer 60, an oxide layer 62 and an electrode 61, wherein the thickness of the oxide layer 62 is usually much greater than 50 Å. The oxide layer 62 is made of an oxide. Please refer to FIG. 1, FIG. 5 and FIG. 6. The characteristics of the metal-oxide-semiconductor structure 6 of the conventional technology is significantly different from the characteristics of the Schottky interface between the Schottky barrier layer 50 and the first electrode 51 of the Schottky diode 5 of the conventional technology. They have different applications and are respectively and preferably used in certain field. In FIG. 1, since the thickness 13 of the nanoscale film interface layer 12 is so thin (greater than 3 Å and smaller than 20 Å) such that the characteristics of the interface formed by the contact of the metal electrode 20 and the nanoscale film interface layer 12 of the Schottky barrier semiconductor device 1 of the present invention is significantly different from the characteristics of the metal-oxide-semiconductor structure 6 of the conventional technology in FIG. 6 but more similar to the characteristics of the Schottky interface (formed by the contact of the first electrode 51 and the Schottky barrier layer 50) of the Schottky diode 5 of the conventional technology in FIG. 5.

In FIG. 1, the nanoscale film interface layer 12 may be made of one oxide or may be made of more than one kinds of oxide. As long as the thickness 13 of the nanoscale film interface layer 12 remains within the range between greater than 3 Å and smaller than 20 Å, the structure of the nanoscale film interface layer 12 may be a single layer structure with single oxide, may be a multi-layers structure with single oxide, or may be a multi-layers structure with multiple oxides. In an embodiment, the nanoscale film interface layer 12 is made of at least one material selected from the group consisting of an aluminum oxide, a silicon oxide, a gallium oxide, a germanium oxide, a nickel oxide, a tantalum oxide and a palladium oxide. In another embodiment, the nanoscale film interface layer 12 is made of at least one material selected from the group consisting of a titanium oxide, a zirconium oxide and a hafnium oxide. In other one embodiment, the nanoscale film interface layer 12 is made of at least one material selected from the group consisting of a niobium oxide, a ruthenium oxide, a zinc oxide, a tungsten oxide, a chromium oxide, a vanadium oxide, an iron oxide, a molybdenum oxide, a cobalt oxide, a rhodium oxide, a copper oxide, a silver oxide, an arsenic oxide and an antimony oxide. In another embodiment, the nanoscale film interface layer 12 is made of at least one material selected from the group consisting of an aluminum oxide, a silicon oxide, a gallium oxide, a germanium oxide, a nickel oxide, a tantalum oxide, a titanium oxide, a zirconium oxide, a hafnium oxide, a niobium oxide, a ruthenium oxide, a zinc oxide, a tungsten oxide, a chromium oxide, a palladium oxide, a vanadium oxide, an iron oxide, a molybdenum oxide, a cobalt oxide, a rhodium oxide, a copper oxide, a silver oxide, an arsenic oxide and an antimony oxide.

In an embodiment, the Schottky barrier layer 10 in FIG. 1 is made of at least one material selected from the group consisting of GaN, GaAs, InP, AlGaN, AlGaAs, InGaAs, InGaP, AlInP and SiC. In another embodiment, the Schottky barrier layer 10 in FIG. 1 is made of at least one material selected from the group consisting of AlN, AlP, AlAs, AlSb, GaP, GaSb, InN, InAs, InSb, AlInAs, AlInSb, GaAsN, GaAsP, GaAsSb, AlGaP, InGaN, InAsSb, InGaSb, AlGaInP, AlGaAsP, InGaAsP, InGaAsSb, InAsSbP, AlInAsP, AlGaAsN, InGaAsN, InAlAsN, GaAsSbN, GaInNAsSb and GaInAsSbP. In other one embodiment, the Schottky barrier layer 10 is made of at least one material selected from the group consisting of group IV compound semiconductor materials, group II-VI compound semiconductor materials and group III-V compound semiconductor materials.

In an embodiment, the thickness 13 of the nanoscale film interface layer 12 is greater than 3 Å and less than 18 Å. In another embodiment, the thickness 13 of the nanoscale film interface layer 12 is greater than 3 Å and less than 15 Å. In one embodiment, the thickness 13 of the nanoscale film interface layer 12 is greater than 3 Å and less than 13 Å. In an embodiment, the thickness 13 of the nanoscale film interface layer 12 is greater than 3 Å and less than 10 Å. In another embodiment, the thickness 13 of the nanoscale film interface layer 12 is greater than 3 Å and less than 8 Å. In one embodiment, the thickness 13 of the nanoscale film interface layer 12 is greater than 3 Å and less than 5 Å. In an embodiment, the thickness 13 of the nanoscale film interface layer 12 is greater than 5 Å and less than 15 Å. In a preferable embodiment, the thickness 13 of the nanoscale film interface layer 12 is greater than 5 Å and less than 18 Å.

In another preferable embodiment, the thickness 13 of the nanoscale film interface layer 12 is greater than 5 Å and less than 12 Å. In one preferable embodiment, the thickness 13 of the nanoscale film interface layer 12 is greater than 5 Å and less than 10 Å. In a preferable embodiment, the thickness 13 of the nanoscale film interface layer 12 is greater than 5 Å and less than 8 Å.

Please refer to FIG. 2, which is the sectional schematic view of an embodiment of the Schottky barrier semiconductor device having a nanoscale film interface of the present invention. In this embodiment, the Schottky barrier semiconductor device 1 is a Schottky diode 2. Its structure comprises a Schottky barrier layer 10, a metal electrode 20 and a second metal electrode 21. The Schottky barrier layer 10 in FIG. 2 has the same structure with the Schottky barrier layer 10 in FIG. 1. A nanoscale film interface layer 12 is formed on a top surface 11 of the Schottky barrier layer 10. The metal electrode 20 is formed on the nanoscale film interface layer 12 such that the metal electrode 20 is contacted with the nanoscale film interface layer 12. The second metal electrode 21 is formed below the Schottky barrier layer 10 and formed an ohmic contact. The nanoscale film interface layer 12 is made of an oxide or at least one oxide. The oxide is deposited on the top surface 11 of the Schottky barrier layer 10 by the Atomic Layer Chemical Vapor Deposition System and combined with the top surface 11 of the Schottky barrier layer 10 to form the nanoscale film interface layer 12, thereby reducing the interface trap of the top surface 11 of the Schottky barrier layer 10. The thickness 13 of the nanoscale film interface layer 12 is within the range between greater than 3 Å and smaller than 20 Å. By depositing the nanoscale film interface layer 12 to reduce the interface trap of the top surface 11 of the Schottky barrier layer 10, thus may improve the current collapse phenomenon of the Schottky diode 2. And due to the nanoscale film interface layer 12 is made of oxide, hence the metal diffusion may be reduced and the leakage current may also be reduced too. In a preferable embodiment, the thickness 13 of the nanoscale film interface layer 12 is within the range greater or equal to 5 Å and smaller or equal to 10 Å.

Please refer to FIG. 2A, which is the sectional schematic view of an embodiment of the Schottky barrier semiconductor device having a nanoscale film interface of the present invention. The main structure is mostly similar to the structure of the embodiment shown in FIG. 2, except that further comprises a substrate 22. The Schottky barrier layer 10 is formed above the substrate 22 and the second metal electrode 21 is formed below the substrate 22. In this embodiment the Schottky barrier semiconductor device 1 is also a Schottky diode 2. In some embodiments, the substrate 22 is made of one material selected from the group consisting of GaAs, sapphire, InP, SiC and GaN.

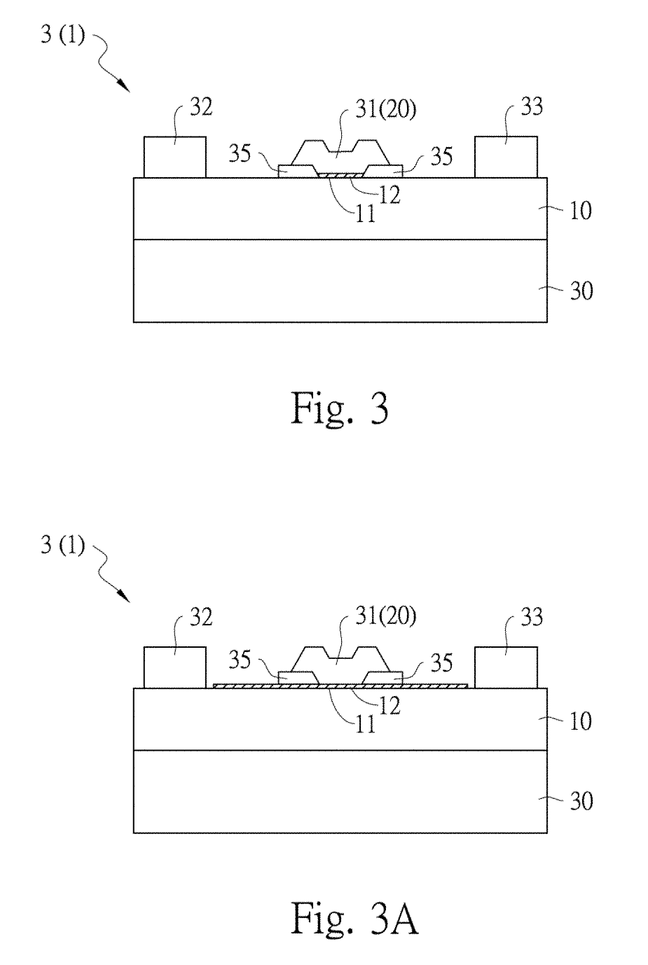

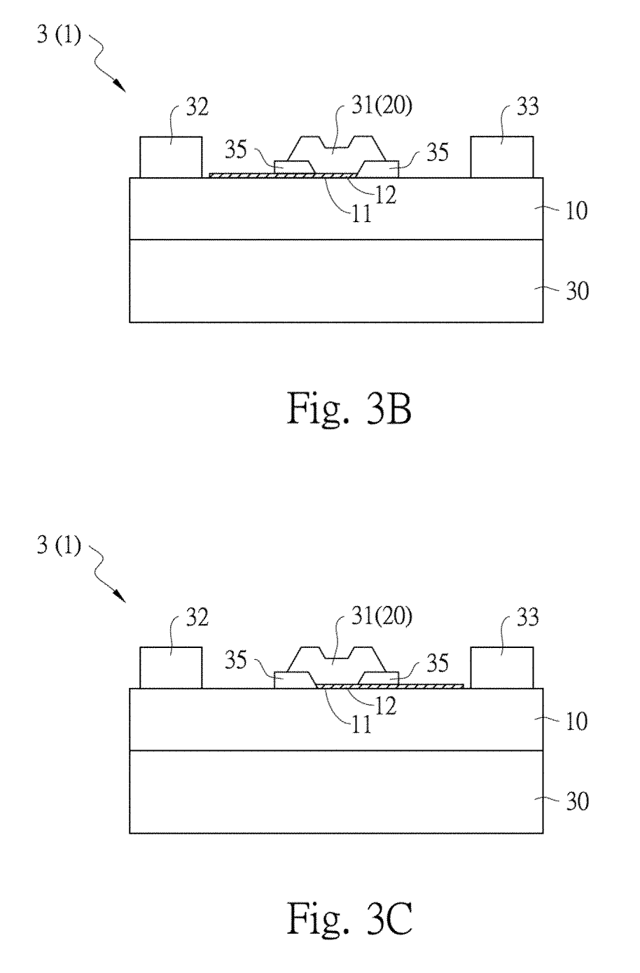

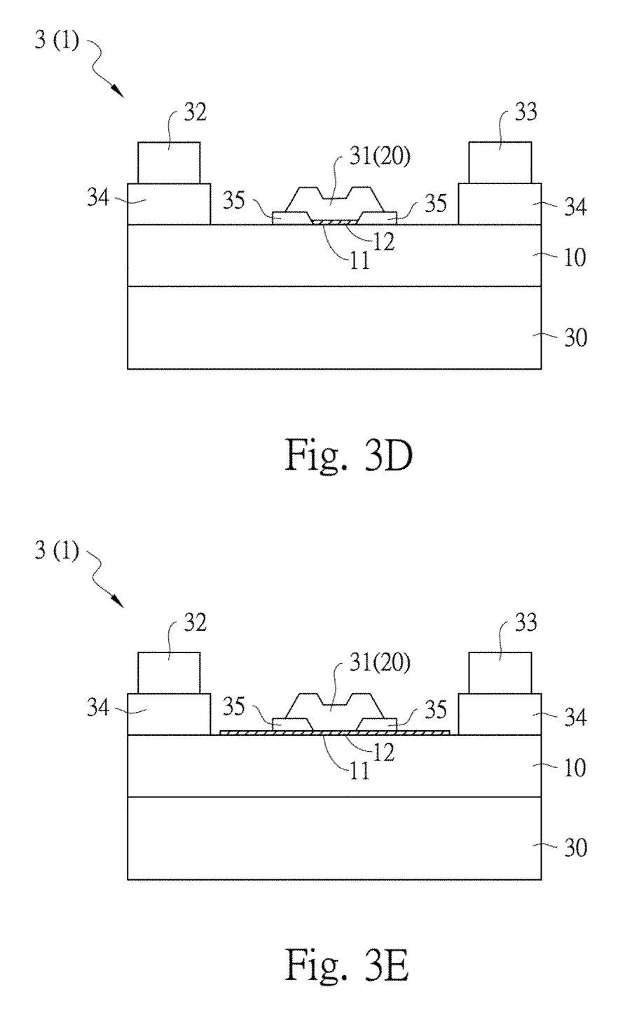

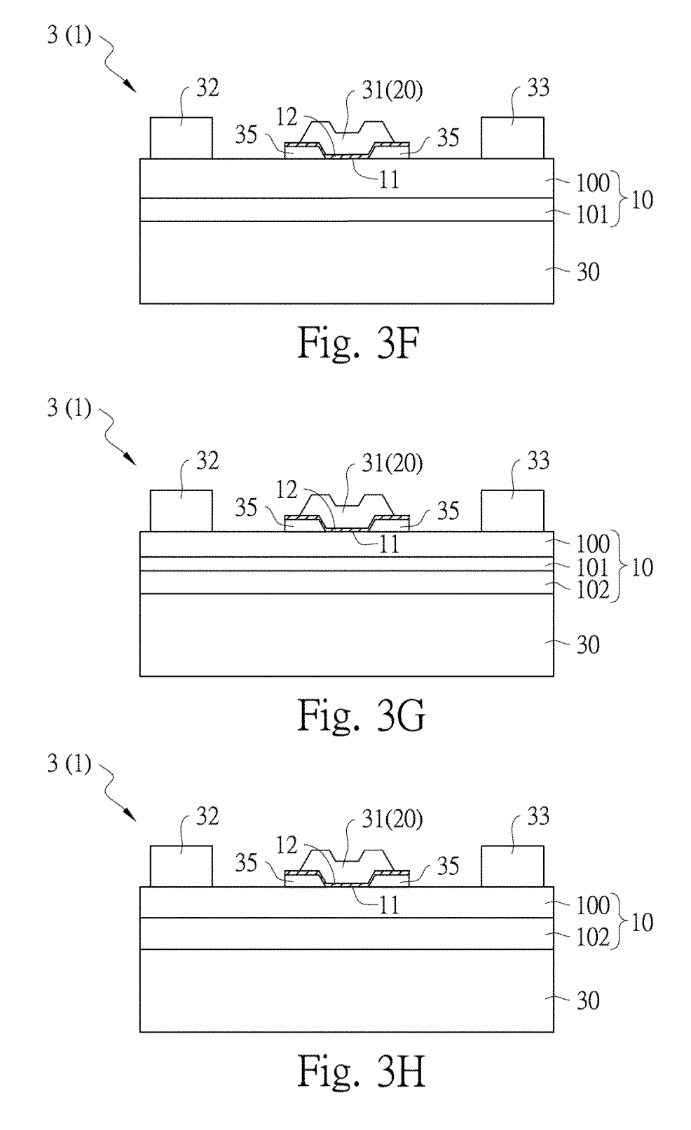

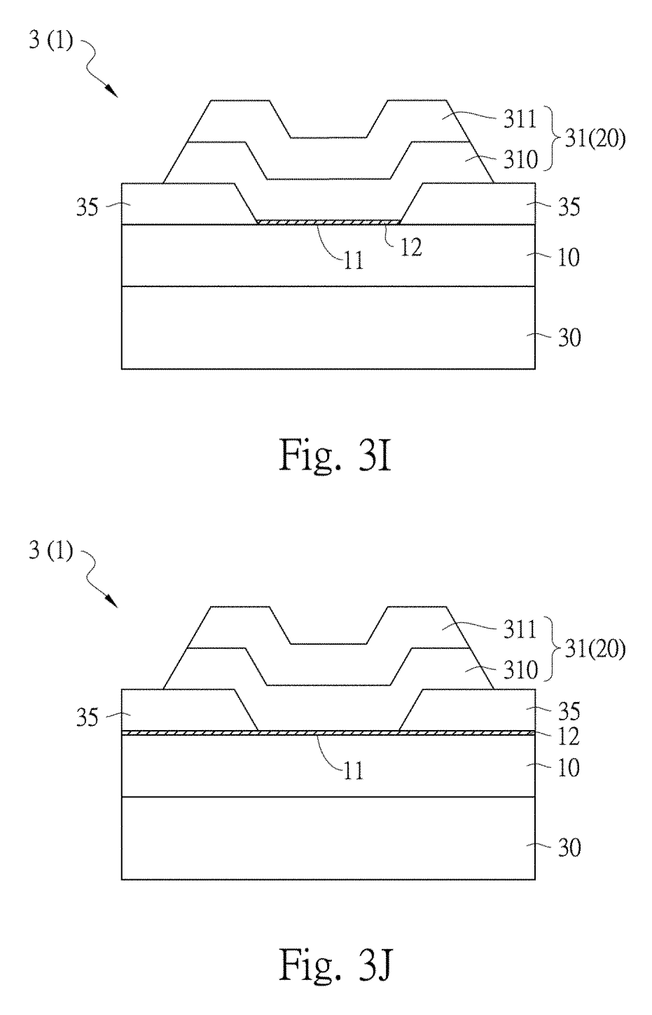

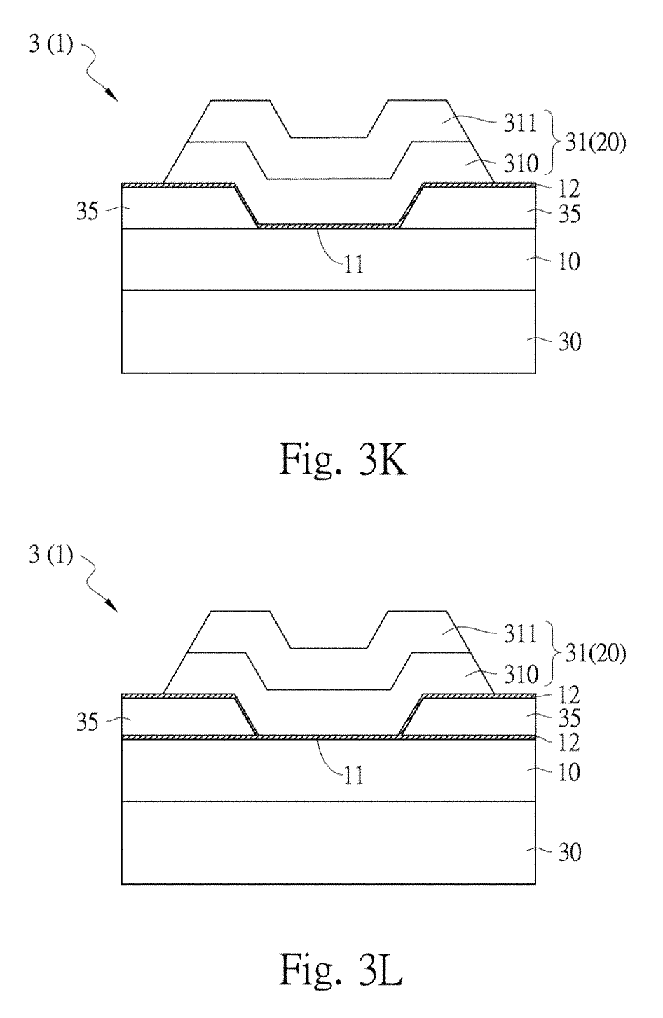

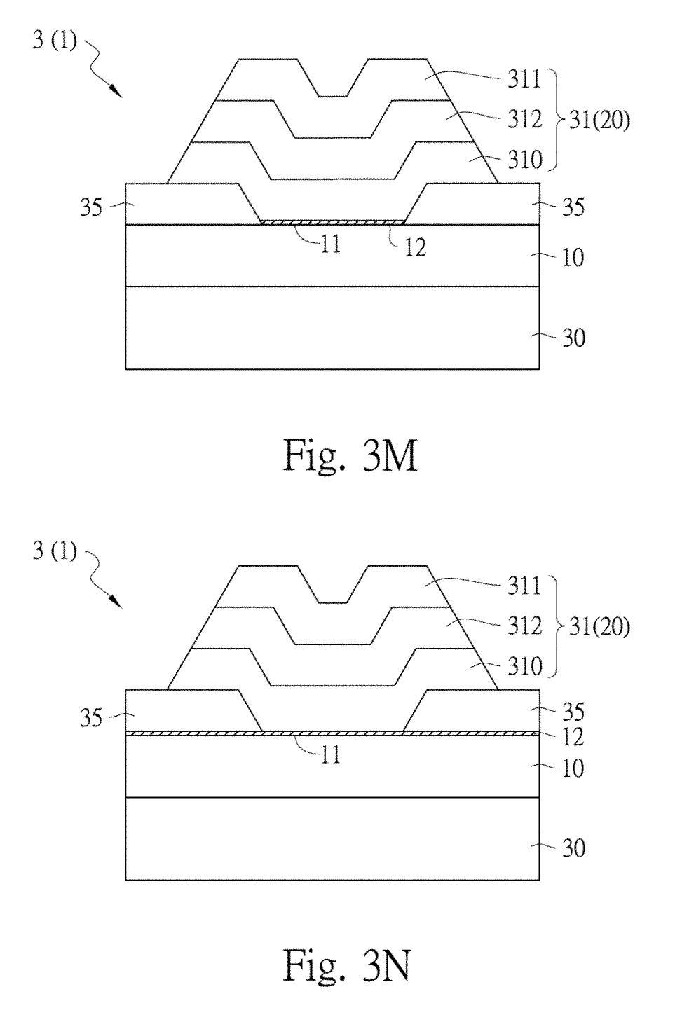

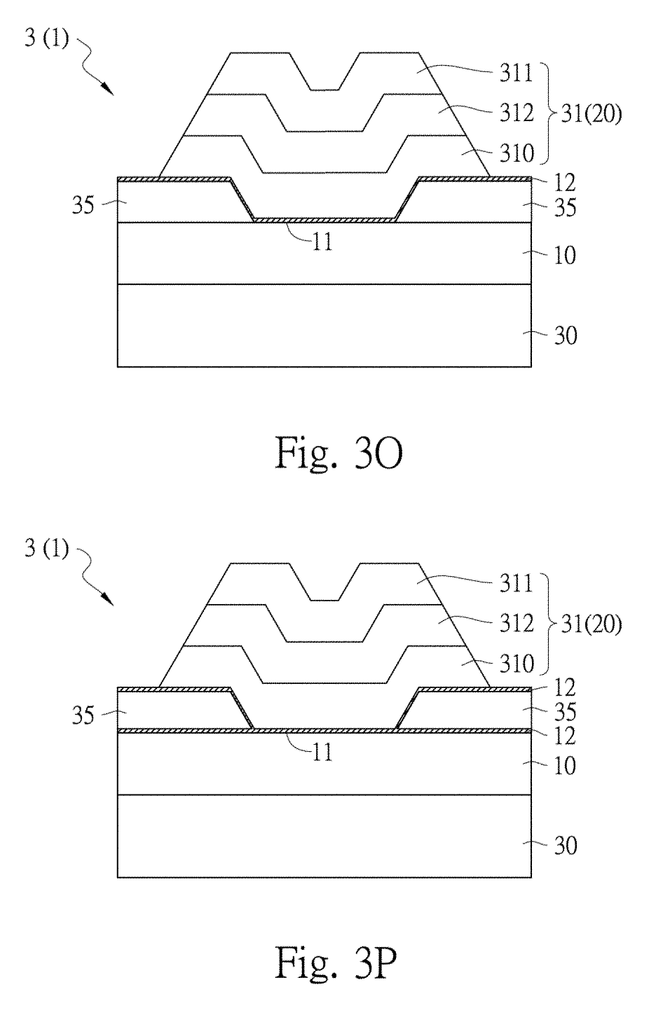

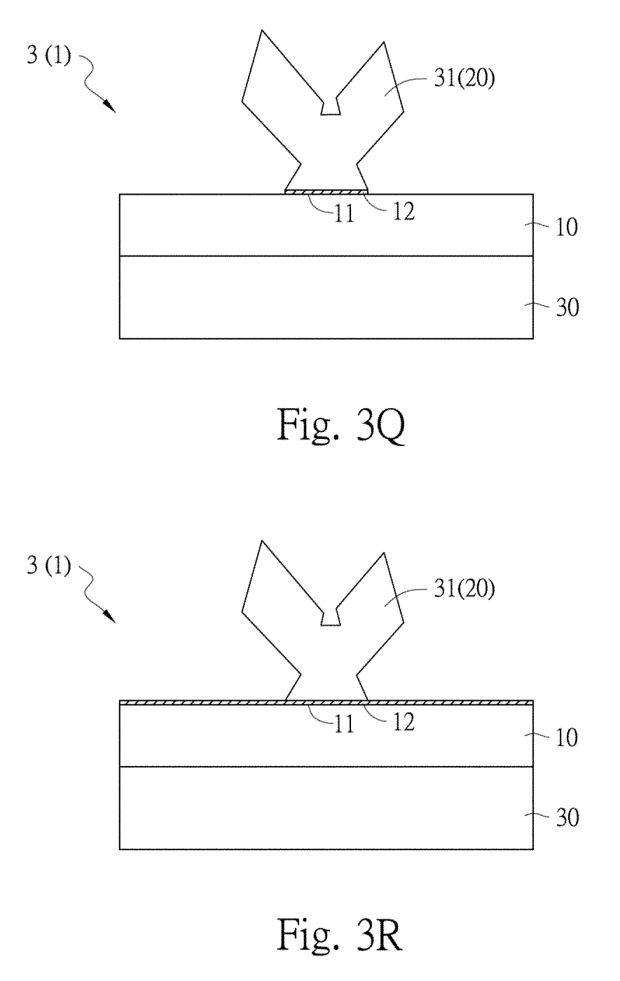

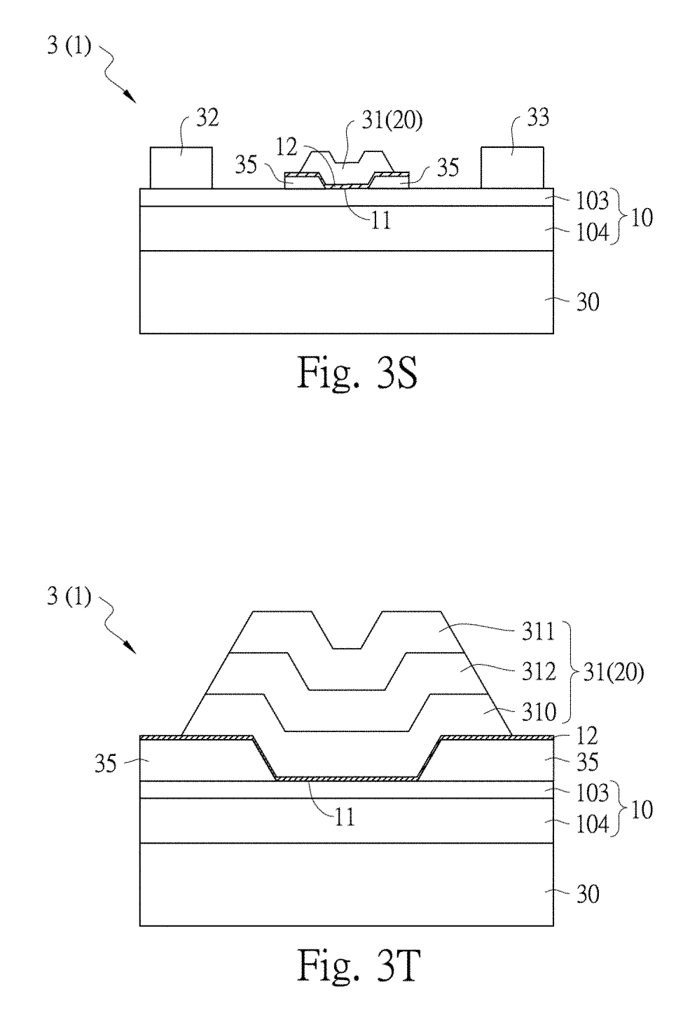

Please refer to FIG. 3, which is the sectional schematic view of an embodiment of the Schottky barrier semiconductor device having a nanoscale film interface of the present invention. In this embodiment, the Schottky barrier semiconductor device 1 is a metal-semiconductor field effect transistor 3. Its structure comprises a substrate 30, a Schottky barrier layer 10, a gate electrode 31, a drain electrode 32, a source electrode 33 and a dielectric layer 35. The Schottky barrier layer 10 in FIG. 3 has the same structure with the Schottky barrier layer 10 in FIG. 1. The Schottky barrier layer 10 is formed on the substrate 30. A nanoscale film interface layer 12 is formed on a top surface 11 of the Schottky barrier layer 10. The gate electrode 31 is formed on the nanoscale film interface layer 12 such that the gate electrode 31 is contacted with the nanoscale film interface layer 12. Usually before forming the gate electrode 31, the dielectric layer 35 is formed on the Schottky barrier layer 10 and the dielectric layer 35 is etched to form a dielectric layer recess. And then the gate electrode 31 is formed on the dielectric layer 35 and covers the dielectric layer recess such that the gate electrode 31 is contacted with the nanoscale film interface layer 12 at the bottom of the dielectric layer recess. The drain electrode 32 and the source electrode 33 are formed at respectively the left and the right sides of the gate electrode 31 on the top surface 11 of the Schottky barrier layer 10. And the drain electrode 32 and the source electrode 33 form the ohmic contact with the Schottky barrier layer 10 respectively. The nanoscale film interface layer 12 is made of an oxide or at least one oxide. The oxide is deposited on the top surface 11 of the Schottky barrier layer 10 by the Atomic Layer Chemical Vapor Deposition System and combined with the top surface 11 of the Schottky barrier layer 10 to form the nanoscale film interface layer 12, thereby reducing the interface trap of the top surface 11 of the Schottky barrier layer 10. The thickness 13 of the nanoscale film interface layer 12 is within the range between greater than 3 Å and smaller than 20 Å. By depositing the nanoscale film interface layer 12 to reduce the interface trap of the top surface 11 of the Schottky barrier layer 10, thus may improve the gate-lag phenomenon and the drain-lag phenomenon of the metal-semiconductor field effect transistor 3. And due to the nanoscale film interface layer 12 is made of oxide, hence the gate metal diffusion may be reduced and the gate leakage current may also be reduced too. In a preferable embodiment, the thickness 13 of the nanoscale film interface layer 12 is within the range greater or equal to 5 Å and smaller or equal to 10 Å. In some embodiments, the substrate 30 is made of one material selected from the group consisting of GaAs, sapphire, InP, SiC and GaN.

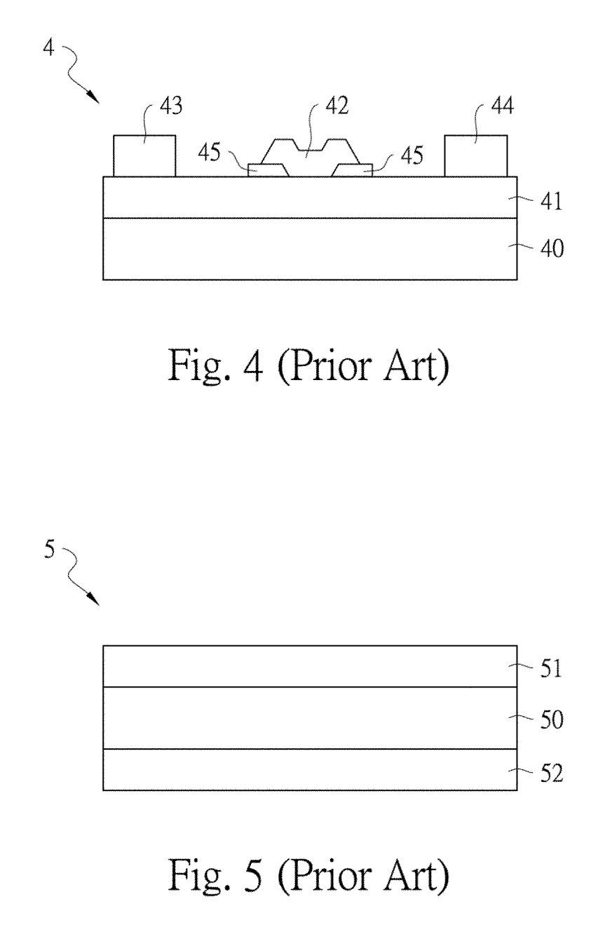

Please refer to FIG. 7, which is the sectional schematic view of the metal-oxide-semiconductor field effect transistor of the conventional technology. The structure of the metal-oxide-semiconductor field effect transistor 7 comprises a substrate 70, a Schottky barrier layer 71, a gate electrode 72, a drain electrode 73, a source electrode 74, an oxide layer 75 and a dielectric layer 76. The Schottky barrier layer 71 is formed on the substrate 70. The oxide layer 75 is formed on the Schottky barrier layer 71. The gate electrode 72 is formed on the oxide layer 75. Usually before forming the gate electrode 72, the dielectric layer 76 is formed on the oxide layer 75 and the dielectric layer 76 is etched to form a dielectric layer recess. And then the gate electrode 72 is formed on the dielectric layer 76 and covers the dielectric layer recess such that the gate electrode 72 is contacted with the oxide layer 75 at the bottom of the dielectric layer recess. The drain electrode 73 and the source electrode 74 are formed at respectively the left and the right sides of the gate electrode 72 on the Schottky barrier layer 71. And the drain electrode 73 and the source electrode 74 form the ohmic contact with the Schottky barrier layer 71 respectively. The thickness of the oxide layer 75 is usually much greater than 50 Å. The oxide layer 75 is made of an oxide. And the metal-oxide-semiconductor structure is formed. Please refer to FIG. 3, FIG. 4 and FIG. 7. Since the metal-oxide-semiconductor structure 6 has been applied to the metal-oxide-semiconductor field effect transistor 7, hence the characteristics of the metal-oxide-semiconductor field effect transistor 7 of the conventional technology is significantly different from the characteristics of the metal-semiconductor field effect transistor 4 of the conventional technology. They have different applications and are respectively and preferably used in certain field. In FIG. 3, since the thickness 13 of the nanoscale film interface layer 12 is so thin (greater than 3 Å and smaller than 20 Å) such that the characteristics of the interface formed by the contact of the gate electrode 31 and the nanoscale film interface layer 12 of the metal-semiconductor field effect transistor 3 of the present invention is significantly different from the characteristics of the metal-oxide-semiconductor field effect transistor 7 of the conventional technology in FIG. 7 but more similar to the characteristics of the Schottky junction (formed by the contact of the gate electrode 42 and the Schottky barrier layer 41) of the metal-semiconductor field effect transistor 4 of the conventional technology in FIG. 4. Therefore, the metal-semiconductor field effect transistor 3 of the present invention may improve the gate-lag phenomenon and the drain-lag phenomenon, reduce gate metal diffusion and reduce gate leakage current. And also the rest of the characteristics of the metal-semiconductor field effect transistor 3 of the present invention may be preserved closer to the characteristics of the metal-semiconductor field effect transistor 4 of the conventional technology.

Since not only the interface trap of the Schottky barrier layer 10 within the interface where the gate electrode 31 is contacted with the nanoscale film interface layer 12 may affect the gate-lag and the drain-lag, but also the interface trap of the Schottky barrier layer 10 within the interface between the drain electrode 32 and the gate electrode 31 and the interface trap of the Schottky barrier layer 10 within the interface between the gate electrode 31 and the source electrode 33 may affect the gate-lag and the drain-lag. Therefore, please refer to FIG. 3A˜FIG. 3C, which are the sectional schematic views of three embodiments of the Schottky barrier semiconductor device having a nanoscale film interface of the present invention. The main structure of the embodiment in FIG. 3A is mostly similar to the structure of the embodiment shown in FIG. 3, except that the range of the nanoscale film interface layer 12 includes the interface where the gate electrode 31 is contacted with the nanoscale film interface layer 12, and the nanoscale film interface layer 12 extended from the gate electrode 31 toward the drain electrode 32 and the source electrode 33. And the dielectric layer 35 is thus formed on the nanoscale film interface layer 12. The main structure of the embodiment in FIG. 3B is mostly similar to the structure of the embodiment shown in FIG. 3, except that the range of the nanoscale film interface layer 12 includes the interface where the gate electrode 31 is contacted with the nanoscale film interface layer 12 and the interface between the drain electrode 32 and the gate electrode 31. And part of the dielectric layer 35 is thus formed on the nanoscale film interface layer 12. The main structure of the embodiment in FIG. 3C is mostly similar to the structure of the embodiment shown in FIG. 3, except that the range of the nanoscale film interface layer 12 includes the interface where the gate electrode 31 is contacted with the nanoscale film interface layer 12 and the interface between the gate electrode 31 and the source electrode 33. And part of the dielectric layer 35 is thus formed on the nanoscale film interface layer 12.

Please refer to FIG. 3D, which is the sectional schematic view of another embodiment of the Schottky barrier semiconductor device having a nanoscale film interface of the present invention. The main structure is mostly similar to the structure of the embodiment shown in FIG. 3, except that further comprises a cap layer 34. The cap layer 34 is formed at the left and the right sides of the gate electrode 31 on the Schottky barrier layer 10. And the drain electrode 32 and the source electrode 33 are formed respectively on the cap layer 34.

Please refer to FIG. 3E, which is the sectional schematic view of an embodiment of the Schottky barrier semiconductor device having a nanoscale film interface of the present invention. The main structure is mostly similar to the structure of the embodiment shown in FIG. 3D, except that the range of the nanoscale film interface layer 12 includes the interface where the gate electrode 31 is contacted with the nanoscale film interface layer 12, and the nanoscale film interface layer 12 extended from the gate electrode 31 toward the drain electrode 32 and the source electrode 33. And the dielectric layer 35 is thus formed on the nanoscale film interface layer 12. In another embodiment, the range of the nanoscale film interface layer 12 includes the interface where the gate electrode 31 is contacted with the nanoscale film interface layer 12 and the interface between the drain electrode 32 and the gate electrode 31 (not shown in Figure). In one other embodiment, the range of the nanoscale film interface layer 12 includes the interface where the gate electrode 31 is contacted with the nanoscale film interface layer 12 and the interface between the gate electrode 31 and the source electrode 33 (not shown in Figure).

Please refer to FIG. 3F˜FIG. 3H, which are the sectional schematic views of the embodiments of the Schottky barrier semiconductor device having a nanoscale film interface of the present invention. The main structure of the embodiment in FIG. 3F is mostly similar to the structure of the embodiment shown in FIG. 3, except that the Schottky barrier layer 10 includes a barrier sub-layer 100 and a channel sub-layer 101. The channel sub-layer 101 is formed on the substrate 30. The barrier sub-layer 100 is formed on the channel sub-layer 101. The nanoscale film interface layer 12 is formed on the top surface 11 of the barrier sub-layer 100 (the Schottky barrier layer 10). The main structure of the embodiment in FIG. 3G is mostly similar to the structure of the embodiment shown in FIG. 3F, except that the Schottky barrier layer 10 further comprises a buffer sub-layer 102. The buffer sub-layer 102 is formed on the substrate 30. And the channel sub-layer 101 is formed on the buffer sub-layer 102. The main structure of the embodiment in FIG. 3H is mostly similar to the structure of the embodiment shown in FIG. 3, except that the Schottky barrier layer 10 includes a barrier sub-layer 100 and a buffer sub-layer 102. The buffer sub-layer 102 is formed on the substrate 30. The barrier sub-layer 100 is formed on the buffer sub-layer 102. The nanoscale film interface layer 12 is formed on the top surface 11 of the barrier sub-layer 100 (the Schottky barrier layer 10).

In some embodiments, the Schottky barrier semiconductor device of the present invention is a high electron mobility transistor (HEMT). The main structure may be mostly similar to any one of the structures of the embodiments shown in FIG. 3˜FIG. 3H.

In the embodiments of FIG. 3˜FIG. 3H, typically the structure of the gate electrode 31 of the metal-semiconductor field effect transistor 3 comprises a plural of layers. Please refer to FIG. 3I˜FIG. 3P for the detailed structure of the gate electrode 31. FIG. 3I˜FIG. 3L are the partial enlarged gate electrode sectional schematic views of the embodiments of the Schottky barrier semiconductor device having a nanoscale film interface of the present invention. The structure of the embodiments shown in FIG. 3I˜FIG. 3L comprises a substrate 30, a Schottky barrier layer 10, a gate electrode 31 and a dielectric layer 35. A nanoscale film interface layer 12 is formed on a top surface 11 of the Schottky barrier layer 10. The gate electrode 31 is formed on the nanoscale film interface layer 12, wherein the gate electrode 31 includes a contact layer 310 and conduct layer 311 such that the contact layer 310 of the gate electrode 31 is contacted with the nanoscale film interface layer 12. The conduct layer 311 is formed on the contact layer 310. Usually before forming the gate electrode 31, the dielectric layer 35 is formed on the Schottky barrier layer 10 and the dielectric layer 35 is etched to form a dielectric layer recess. And then the gate electrode 31 is formed on the dielectric layer 35 and covers the dielectric layer recess such that the contact layer 310 of the gate electrode 31 is contacted with the nanoscale film interface layer 12 at the bottom of the dielectric layer recess. The nanoscale film interface layer 12 is made of an oxide or at least one oxide. The thickness 13 of the nanoscale film interface layer 12 is within the range between greater than 3 Å and smaller than 20 Å. In the embodiment of FIG. 3I, the range of the nanoscale film interface layer 12 includes the interface where the contact layer 310 of the gate electrode 31 is contacted with the nanoscale film interface layer 12. In the embodiment of FIG. 3J, the range of the nanoscale film interface layer 12 includes the interface where the contact layer 310 of the gate electrode 31 is contacted with the nanoscale film interface layer 12, and the nanoscale film interface layer 12 extended from the gate electrode 31 toward the left and the right sides of the gate electrode 31. And the dielectric layer 35 is thus formed on the nanoscale film interface layer 12. In the embodiment of FIG. 3K, the range of the nanoscale film interface layer 12 includes the interface where the contact layer 310 of the gate electrode 31 is contacted with the nanoscale film interface layer 12, an inner surface of the dielectric layer recess and a top surface of the dielectric layer 35. In the embodiment of FIG. 3L, the range of the nanoscale film interface layer 12 includes the interface where the contact layer 310 of the gate electrode 31 is contacted with the nanoscale film interface layer 12, an inner surface of the dielectric layer recess, a top surface of the dielectric layer 35, and the nanoscale film interface layer 12 extended from the gate electrode 31 toward the left and the right sides of the gate electrode 31. FIG. 3M˜FIG. 3P are the partial enlarged gate electrode sectional schematic views of the embodiments of the Schottky barrier semiconductor device having a nanoscale film interface of the present invention. The structures of the embodiments of FIG. 3M˜FIG. 3P are similar to the structures of the embodiments of FIG. 3I˜FIG. 3L, except that the gate electrode 31 further comprises a diffusion barrier layer 312. The diffusion barrier layer 312 is formed on the contact layer 310, and the conduct layer 311 is formed on the diffusion barrier layer 312. In some embodiments, the Schottky barrier semiconductor device of the present invention is a GaN high electron mobility transistor (HEMT), which may have the structures of the gate electrode 31 shown in FIG. 3I˜FIG. 3P.

Please refer to FIG. 3Q and FIG. 3R, which are the partial enlarged gate electrode sectional schematic views of the embodiments of the Schottky barrier semiconductor device having a nanoscale film interface of the present invention. The structure of the embodiments of FIG. 3Q and FIG. 3R comprises a substrate 30, a Schottky barrier layer 10 and a gate electrode 31. A nanoscale film interface layer 12 is formed on a top surface 11 of the Schottky barrier layer 10. The gate electrode 31 is formed on the nanoscale film interface layer 12 such that the gate electrode 31 is contacted with the nanoscale film interface layer 12. The nanoscale film interface layer 12 is made of an oxide or at least one oxide. The thickness 13 of the nanoscale film interface layer 12 is within the range between greater than 3 Å and smaller than 20 Å. In the embodiment of FIG. 3Q, the range of the nanoscale film interface layer 12 includes the interface where the gate electrode 31 is contacted with the nanoscale film interface layer 12. In the embodiment of FIG. 3R, the range of the nanoscale film interface layer 12 includes the interface where the gate electrode 31 is contacted with the nanoscale film interface layer 12, and the nanoscale film interface layer 12 extended from the gate electrode 31 toward the left and the right sides of the gate electrode 31. In some embodiments, the Schottky barrier semiconductor device of the present invention is a GaAs high electron mobility transistor (HEMT), which may have the structures of the gate electrode 31 shown in FIG. 3Q and FIG. 3R.

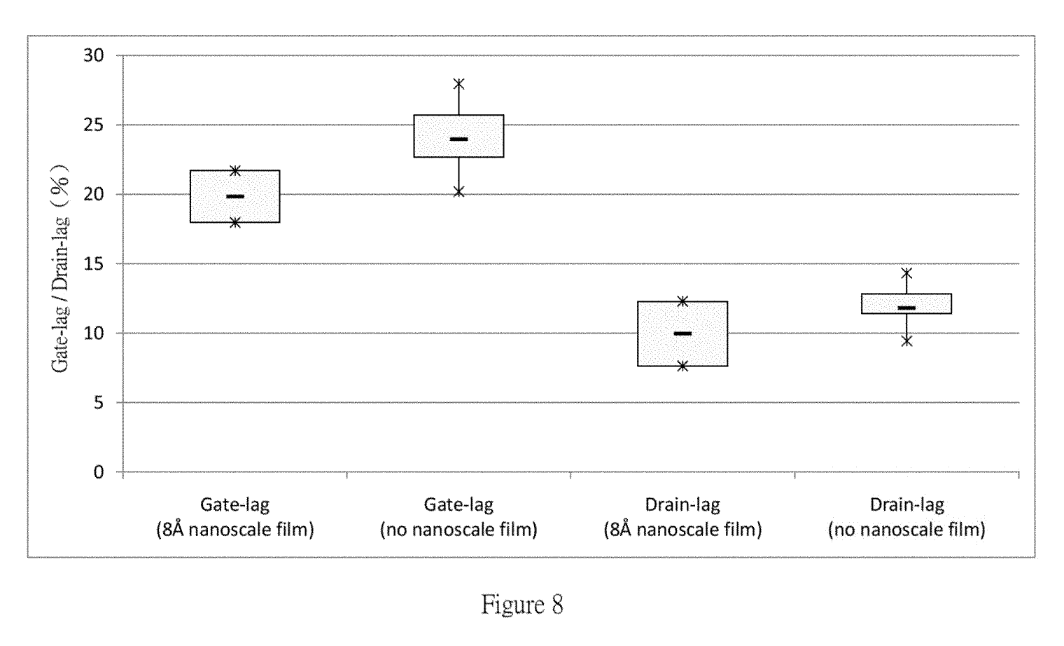

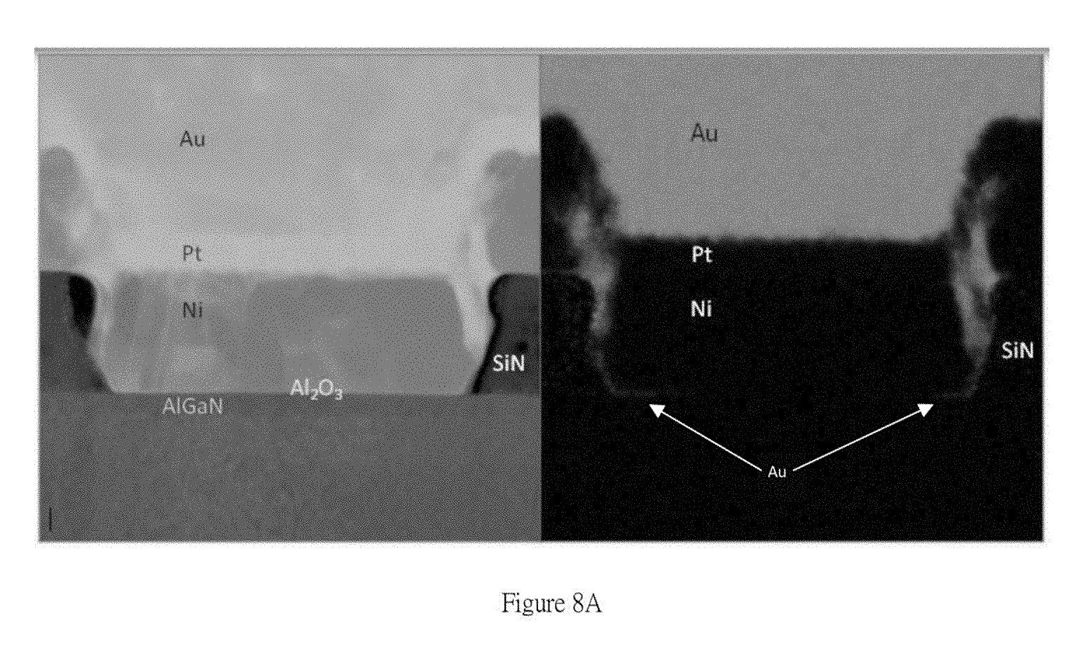

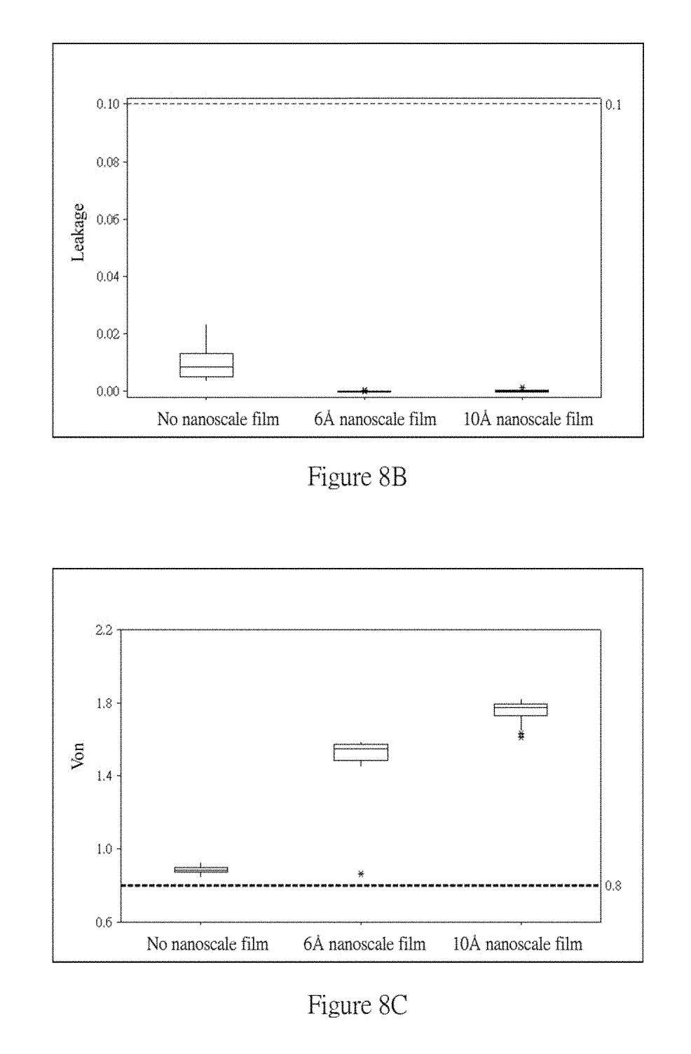

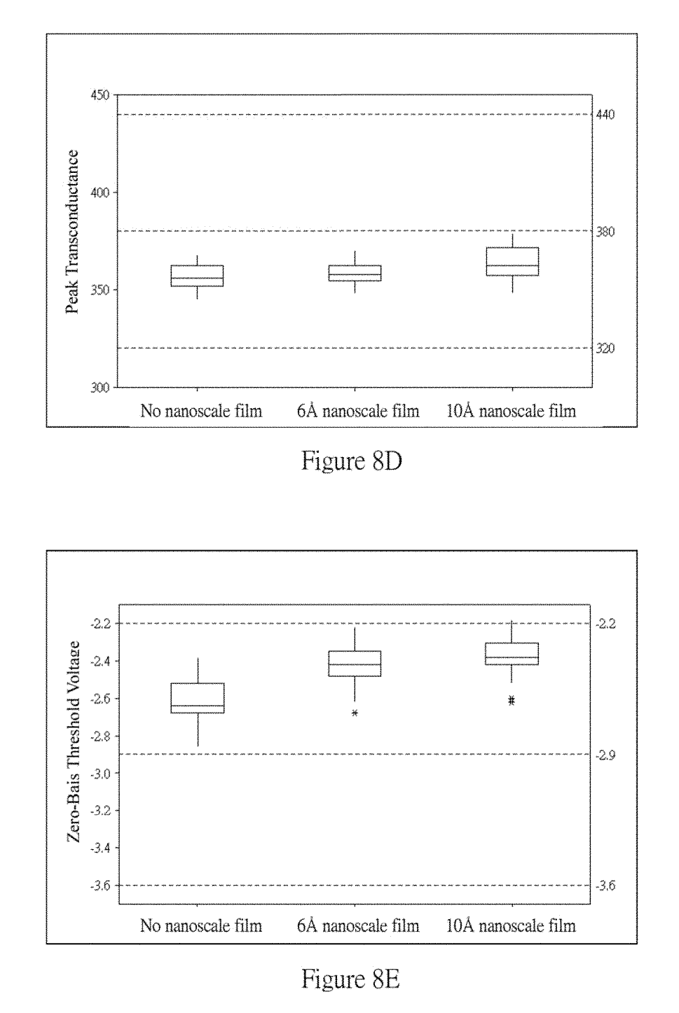

Please refer to FIG. 3S and FIG. 3T, which are respectively the sectional schematic view and the partial enlarged gate electrode sectional schematic view of an embodiment of the Schottky barrier semiconductor device having a nanoscale film interface of the present invention. In the embodiments, the Schottky barrier semiconductor device of the present invention is a GaN high electron mobility transistor. The main structure is mostly similar to the structure of the embodiment shown in FIG. 3 (and FIG. 30), except that the Schottky barrier layer 10 includes a GaN sub-layer 104 and a AlGaN sub-layer 103. The GaN sub-layer 104 is formed on the substrate 30. The AlGaN sub-layer 103 is formed on the GaN sub-layer 104. The nanoscale film interface layer 12 is made of Al₂O₃. The substrate 30 is made of SiC. The dielectric layer 35 is made of SiN. The structure of the gate electrode 31 is as shown in FIG. 3T (mostly similar to the structure of the embodiment shown in FIG. 30). The contact layer 310 is made of Ni. The conduct layer 311 is made of Au. The diffusion barrier layer 312 is made of Pt. According to the structure described the above, applicant made three kinds of GaN high electron mobility transistors having respectively 6 Å, 8 Å and 10 Å of the thickness 13 of the nanoscale film interface layer 12. And then measuring the electrical characteristics of these three kinds of GaN high electron mobility transistors having respectively different thickness 13 of the nanoscale film interface layer 12, and making the comparison with that of the GaN high electron mobility transistors having no nanoscale film interface layer. The results are shown respectively as in FIG. 8˜FIG. 8E.

All the embodiments of the present invention comprises the Schottky barrier layer 10, the nanoscale film interface layer 12 formed on the top surface 11 of the Schottky barrier layer 10, and the metal electrode 20 (or in some embodiments the gate electrode 31), as shown in FIG. 1. The nanoscale film interface layer 12 is made of an oxide or at least one oxide. In addition to the aforementioned method that to deposit the oxide on the top surface 11 of the Schottky barrier layer 10 by the Atomic Layer Chemical Vapor Deposition System to form the nanoscale film interface layer 12, there are some other methods may also form the nanoscale film interface layer 12. For example, forming a metal oxide of the nanoscale film interface layer 12, by firstly evaporating depositing a metal which is not oxidized on the top surface 11 of the Schottky barrier layer 10, and then introducing oxygen or gas containing oxygen, such that the surface of the metal is oxidized to form a nanoscale film (oxide) interface layer 12 having the metal oxide. A thickness 13 of the nanoscale film (oxide) interface layer 12 is greater than 3 Å and less than 20 Å. In a preferable embodiment, the thickness 13 of the nanoscale film (oxide) interface layer 12 is within the range greater or equal to 5 Å and smaller or equal to 10 Å.

In the embodiments of FIGS. 3A˜3C, 3E, 3J, 3L, 3N and 3P, the range of the nanoscale film interface layer 12 includes the interface where the gate electrode 31 is contacted with the nanoscale film interface layer 12 and the nanoscale film interface layer 12 extended from the gate electrode 31 toward one or both of the left and the right sides of the gate electrode 31. Within the range of the interface where the metal electrode 20 (or gate electrode 31) is contacted with the nanoscale film interface layer 12, the thickness 13 of the nanoscale film interface layer 12 is the same as aforementioned within the range between greater than 3 Å and smaller than 20 Å. In a preferable embodiment, the thickness 13 of the nanoscale film interface layer 12 is within the range greater or equal to 5 Å and smaller or equal to 10 Å. While the nanoscale film interface layer 12 extended from the gate electrode 31 toward one or both of the left and the right sides of the gate electrode 31, the thickness of the nanoscale film interface layer 12 may be equal to or greater than the thickness 13 of the nanoscale film interface layer 12 of the range of the interface where the metal electrode 20 (or gate electrode 31) is contacted with the nanoscale film interface layer 12.

Please refer to FIG. 8, which is the comparison diagram of gate-lag and drain-lag of an embodiment of the Schottky barrier semiconductor device having a nanoscale film interface of the present invention and the metal-semiconductor field effect transistor of the conventional technology. The thickness 13 of the nanoscale film interface layer 12 of the GaN high electron mobility transistor of the embodiment is 8 Å. It is obvious from the result that the GaN high electron mobility transistor of the present invention may indeed significantly reduce the gate-lag. And the drain-lag may also be reduced considerably.

Please refer to FIG. 8A, which is the gate metal diffusion analysis diagram of an embodiment of the Schottky barrier semiconductor device having a nanoscale film interface of the present invention. The thickness 13 of the nanoscale film interface layer 12 of the GaN high electron mobility transistor of the embodiment is 8 Å. The GaN high electron mobility transistor of the embodiment is respectively scanned by the scanning electron microscope (SEM) and analyzed by the energy-dispersive X-ray spectroscope (EDS). The result scanned by the scanning electron microscope is shown in the left hand side of FIG. 8A, which shows that the structure near the gate electrode 31. The result analyzed by the energy-dispersive X-ray spectroscope is shown in the right hand side of FIG. 8A. It is obvious shown from the result that the material gold of the conduct layer indeed diffuses downwardly. However in the end, the material gold diffusing downwardly will be stopped by the nanoscale film interface layer 12. Thus the gate leakage current of the GaN high electron mobility transistor of the present invention will also be reduced too.

Please refer to FIG. 8B˜FIG. 8E, which are respectively the comparison diagrams of leakage current, Von, peak transconductance and zero-bais threshold voltage of two embodiments of the Schottky barrier semiconductor device having a nanoscale film interface of the present invention and the metal-semiconductor field effect transistor of the conventional technology. The thicknesses 13 of the nanoscale film interface layer 12 of the GaN high electron mobility transistors of these two embodiments are respectively 6 A and 10 A. The result in FIG. 8B shows that no matter the thickness 13 of the nanoscale film interface layer 12 is 6 A or 10 A, the leakage current of the GaN high electron mobility transistor of the present invention will be significantly reduced. The result in FIG. 8C shows that no matter the thickness 13 of the nanoscale film interface layer 12 is 6 A or 10 A, the Von voltage of the GaN high electron mobility transistor of the present invention will be significantly raised so as to sustain higher voltage and higher current. The results in FIG. 8D and FIG. 8E show that no matter the thickness 13 of the nanoscale film interface layer 12 is 6 A or 10 A, the peak transconductance and the zero-bais threshold voltage of the GaN high electron mobility transistor of the present invention will be slightly higher (higher is superior), which means that these characteristics of the GaN high electron mobility transistor of the present invention have not much difference from that of the GaN high electron mobility transistor of the conventional technology.

As disclosed in the above description and attached drawings, the present invention can provide a Schottky barrier semiconductor device having a nanoscale film interface. It is new and can be put into industrial use.

Although the embodiments of the present invention have been described in detail, many modifications and variations may be made by those skilled in the art from the teachings disclosed hereinabove. Therefore, it should be understood that any modification and variation equivalent to the spirit of the present invention be regarded to fall into the scope defined by the appended claims.

What is claimed is:

1. A Schottky barrier semiconductor device having a nanoscale film interface comprises:
a Schottky barrier layer, wherein a nanoscale film interface layer is formed on a top surface of said Schottky barrier layer, wherein a thickness of said nanoscale film interface layer is greater than 3 Å and less than 20 Å, said nanoscale film interface layer is made of at least one oxide; and
a metal electrode formed on said nanoscale film interface layer and contacted with said nanoscale film interface layer.

2. The Schottky barrier semiconductor device having a nanoscale film interface according to claim 1, wherein said nanoscale film interface layer is made of at least one material selected from the group consisting of an aluminum oxide, a silicon oxide, a gallium oxide, a germanium oxide, a nickel oxide, a tantalum oxide and a palladium oxide.

3. The Schottky barrier semiconductor device having a nanoscale film interface according to claim 1, wherein said Schottky barrier semiconductor device is a Schottky diode.

4. The Schottky barrier semiconductor device having a nanoscale film interface according to claim 3, further comprising a second metal electrode, wherein said second metal electrode is formed on a bottom surface of said Schottky barrier layer, and said second metal electrode and said Schottky barrier layer form an ohmic contact.

5. The Schottky barrier semiconductor device having a nanoscale film interface according to claim 3, further comprising a substrate and a second metal electrode, wherein said Schottky barrier layer is formed above said substrate, said second metal electrode is formed below said substrate.

6. The Schottky barrier semiconductor device having a nanoscale film interface according to claim 1, further comprising a substrate, wherein said Schottky barrier layer is formed on said substrate.

7. The Schottky barrier semiconductor device having a nanoscale film interface according to claim 6, wherein said substrate is made of one material selected from the group consisting of GaAs, sapphire, InP, SiC and GaN.

8. The Schottky barrier semiconductor device having a nanoscale film interface according to claim 6, wherein said Schottky barrier semiconductor device is a high electron mobility transistor or a metal-semiconductor field transistor.

9. The Schottky barrier semiconductor device having a nanoscale film interface according to claim 8, wherein said metal electrode is a gate electrode.

10. The Schottky barrier semiconductor device having a nanoscale film interface according to claim 9, wherein said gate electrode includes a conduct layer and a contact layer, wherein said contact layer is contacted with said nanoscale film interface layer.

11. The Schottky barrier semiconductor device having a nanoscale film interface according to claim 10, wherein said gate electrode further comprises a diffusion barrier layer, wherein said diffusion barrier layer is formed in between said contact layer and said conduct layer.

12. The Schottky barrier semiconductor device having a nanoscale film interface according to claim 8, further comprising a source electrode and a drain electrode, wherein said source electrode and said drain electrode are formed at respectively the left and the right sides of said metal electrode on said Schottky barrier layer.

13. The Schottky barrier semiconductor device having a nanoscale film interface according to claim 12, further comprising a cap layer, wherein said cap layer is formed between said source electrode and said Schottky barrier layer and between said drain electrode and said Schottky barrier layer.

14. The Schottky barrier semiconductor device having a nanoscale film interface according to claim 8, wherein said Schottky barrier layer comprises a barrier sub-layer and a channel sub-layer, wherein said barrier sub-layer is formed on said channel sub-layer.

15. The Schottky barrier semiconductor device having a nanoscale film interface according to claim 14, wherein said Schottky barrier layer further comprises a buffer sub-layer, wherein said channel sub-layer is formed on said buffer sub-layer.

16. The Schottky barrier semiconductor device having a nanoscale film interface according to claim 8, wherein said Schottky barrier layer comprises a barrier sub-layer and a buffer sub-layer, wherein said barrier sub-layer is formed on said buffer sub-layer.

17. The Schottky barrier semiconductor device having a nanoscale film interface according to claim 1, wherein said Schottky barrier layer is made of at least one material selected from the group consisting of GaN, GaAs, InP, AlGaN, AlGaAs, InGaAs, InGaP, AlInP and SiC.

18. The Schottky barrier semiconductor device having a nanoscale film interface according to claim 1, wherein said Schottky barrier layer is made of at least one material selected from the group consisting of group IV compound semiconductor materials, group II-VI compound semiconductor materials and group III-V compound semiconductor materials.

19. A Schottky barrier semiconductor device having a nanoscale film oxide interface comprising:
a Schottky barrier layer, wherein a top surface of said Schottky barrier layer is oxidized to form a nanoscale film oxide interface layer, wherein a thickness of said nanoscale film oxide interface layer is greater than 3 Å and less than 20 Å; and
a metal electrode formed on said top surface of said Schottky barrier layer and contacted with said nanoscale film oxide interface layer.

20. The Schottky barrier semiconductor device having a nanoscale film oxide interface according to claim 19, wherein said nanoscale film oxide interface layer is made of at least one material selected from the group consisting of an aluminum oxide, a silicon oxide, a gallium oxide, a germanium oxide, a nickel oxide, a tantalum oxide and a palladium oxide.

21. The Schottky barrier semiconductor device having a nanoscale film oxide interface according to claim 19, wherein said Schottky barrier layer is made of at least one material selected from the group consisting of GaN, GaAs, InP, AlGaN, AlGaAs, InGaAs, InGaP, AlInP and SiC.
